(19) United States
(12) Patent Application Publication
(10) Pub. No.: US 2026/0115839 A1
(43) Pub. Date: Apr. 30, 2026

(54) WELDMENTS, CHAMBER ARRANGEMENTS AND SEMICONDUCTOR PROCESSING SYSTEMS INCLUDING WELDMENTS, AND METHOD OF MAKING WELDMENTS FOR CHAMBER ARRANGEMENTS AND SEMICONDUCTOR PROCESSING SYSTEMS

(71) Applicant: ASM IP Holding B.V., Almere (NL)

(72) Inventors: Felix Rabinovich, Scottsdale, AZ (US); Amin Azimi, Phoenix, AZ (US); Samer Banna, Phoenix, AZ (US); Yoram Berger, Chandler, AZ (US)

(21) Appl. No.: 19/369,565

(22) Filed: Oct. 27, 2025

Related U.S. Application Data
(60) Provisional application No. 63/713,974, filed on Oct. 30, 2024.

(51) Int. Cl. B23K 28/00; B23K 37/00; B23K 101/40; B23K 103/00; H01L 21/67

(52) U.S. Cl. CPC B23K 28/00; B23K 37/00; H10P 72/0421; B23K 2101/40; B23K 2103/52

(57) ABSTRACT

A weldment includes a channel body formed from a ceramic material and having a plate portion, and first and second sidewall portions. The plate portion of the channel body has first and second surfaces. The first sidewall portion extends from the plate portion and is substantially orthogonal relative to the first surface of the plate portion of the channel body. The second sidewall portion is spaced apart from the first sidewall portion of the channel body and is substantially parallel to the first sidewall portion. The channel body has a single, one-piece construction with no welds formed using a subtractive manufacturing technique to limit optical effects associated with dimensional variation otherwise introduced into the channel body by welding. Chamber arrangements and semiconductor processing systems including weldments, methods of making weldments, and related methods of depositing material layers and/or removing material form substrates supported within weldments are also described.

### CROSS-REFERENCE TO RELATED APPLICATIONS

This application is a nonprovisional of, and claims priority to and the benefit of, U.S. Provisional Ser. No. 63/713,974 , filed Oct. 30, 2024, which is hereby incorporated by reference herein.

### FIELD OF INVENTION

The present disclosure generally relates to weldments, and more particularly, to methods of making weldments using subtractive manufacturing techniques.

### BACKGROUND OF THE DISCLOSURE

Structures, such as ceramic structures, may be formed by fabricating discrete piece parts and thereafter welding the piece parts to one another to form a weldment. Welding generally requires heating the piece parts being joined to relatively high temperature such that molten material may be introduced between the parts and thereafter permitted to solidify between the piece parts, the solidified material coupling the piece parts to one another. One challenge to forming such weldments is the tendency the heat employed during the welding process to locally change the mechanical properties of the material forming the piece parts being joined by the weld, such as by making the material relatively brittle and prone to fracture. And while the changes to the mechanical properties of the material may be reversed (at least in part) using a post-welding heat treatment operation, heat treating weldments adds time and complexity to the weldment fabrication process, for example due to time required to heat and thereafter cool the weldment, generally according to the number of separate parts and welds required to fabricate the weldment.

Such systems and methods have generally been acceptable for their intended purpose. However, there remains a need in the art for improved weldments, chamber arrangements and semiconductor processing systems including weldments, and methods of making weldments. The present disclosure provides a solution to this need.

### SUMMARY OF THE DISCLOSURE

A weldment is provided. The weldment includes a channel body formed from a ceramic material and having a plate portion, a first sidewall portion, and a second sidewall portion. The plate portion of the channel body has a first surface and a second surface. The first sidewall portion extends from the plate portion and is substantially orthogonal relative to the first surface of the plate portion of the channel body. The second sidewall portion is spaced apart from the first sidewall portion of the channel body and is substantially parallel to the first sidewall portion of the channel body. The channel body has a single, one-piece construction with no welds formed using a subtractive manufacturing technique to limit optical effects associated with dimensional variation otherwise introduced into the channel body by welding.

In addition to one or more of the features described above, or as an alternative, further examples may include that the channel body has two or more channel body rib portions extending from the second surface of the plate portion. The two or more channel body rib portions may be formed using the subtractive manufacturing technique.

In addition to one or more of the features described above, or as an alternative, further examples may include that the two or more channel body rib portions are substantially orthogonal relative to the first sidewall portion of the channel body.

In addition to one or more of the features described above, or as an alternative, further examples may include a plate body formed from the ceramic material and separated from the plate portion of the channel body by the first sidewall portion and the second sidewall portion of the channel body, a first sidewall weld coupling the plate body to the first sidewall, and a second sidewall weld coupling the plate body to the second sidewall of the channel body. The second sidewall weld may be substantially parallel to the first sidewall weld.

In addition to one or more of the features described above, or as an alternative, further examples may include that one or more of the channel body rib portions spans the plate portion of the channel body. The first sidewall portion may have two or more of first sidewall rib portion each extending from respective ones of the two or more channel body rib portions defined using a wire sawing technique. The second sidewall portion may have two or more second sidewall rib portions each extending from the respective ones of the two or more chamber body rib portions defined using a wire sawing technique.

In addition to one or more of the features described above, or as an alternative, further examples may include the plate body defines a passthrough. The weldment may further include a tubulation body separated from the channel body by the plate body. A tubulation body weld may couple the tubulation body to the plate body.

In addition to one or more of the features described above, or as an alternative, further examples may include that the plate body has an interior surface and an exterior surface with two or more plate body rib portions extending therefrom. The interior surface of the plate body may face the channel body. The plate body may have singular, one-piece construction with no welds formed using a subtractive manufacturing technique to limit optical effects associated with dimensional variation otherwise introduce into the channel body by welding.

In addition to one or more of the features described above, or as an alternative, further examples may include that the channel body has two or more rib portions extending from the first sidewall portion of the channel body. The two or more rib portions extending from the plate body may be joined to the plurality of rib portions extending from the first sidewall portion by intervening welds.

In addition to one or more of the features described above, or as an alternative, further examples may include an injection flange body abutting the channel body. An injection end weld may couple the injection flange body to the plate portion of the channel body, the first sidewall portion of the channel body, and the second sidewall portion of the channel body.

In addition to one or more of the features described above, or as an alternative, further examples may include a shelf body formed from the ceramic material having a shelf portion separating the first sidewall portion of the channel body from the second sidewall portion of the channel body and an end rib portion extending from the shelf portion and substantially orthogonal to the shelf portion of the shelf body. A first shelf body-to-first sidewall weld may couple the end rib portion of the shelf body to the first sidewall portion of the channel body. A second shelf body-to-second sidewall weld may couple the end rib portion of the second sidewall portion of the channel body. The shelf body may have a single, one-piece construction with no welds formed using a subtractive manufacturing technique to limit fluid flow effects associated with dimensional variation otherwise introduced into the shelf portion of the shelf body by welding the shelf portion of the shelf body to the end rib portion of the shelf body.

In addition to one or more of the features described above, or as an alternative, further examples may include an exhaust flange body abutting the channel body. An exhaust end weld may couple the exhaust flange body to the shelf portion of the shelf body, the first sidewall portion of the channel body, and the second sidewall portion of the channel body.

In addition to one or more of the features described above, or as an alternative, further examples may include that the subtractive manufacturing technique used to form the channel body of the weldment includes at least a wire sawing operation. The channel body may be machined following the wire sawing operation.

In addition to one or more of the features described above, or as an alternative, further examples may include a slab, e.g., a channel body slab, removed from a singular one-piece workpiece during forming of the channel body using the subtractive manufacturing technique.

A semiconductor processing system is provided. The semiconductor processing system includes a process fluid source including a silicon-containing material layer precursor, a chamber arrangement, and exhaust source. The chamber arrangement may be coupled to the process fluid source, include a weldment as described above, and a substrate support. The substrate support may be arranged within an interior of the weldment and supported therein for rotation about a rotation axis. The substrate support may be configured to seat thereon a substrate during at least one of deposition of a material layer onto the substrate and removal of material from the substrate. The weldment may couple the exhaust source to the process fluid source.

A method of making a weldment is provided. The method includes forming a channel body from a single, one-piece channel body workpiece formed from a ceramic material, the channel body having a plate portion with a first surface and a second surface, a first sidewall portion extending from the plate portion and substantially orthogonal relative to the first surface of the plate portion, and a second sidewall portion spaced apart from the first sidewall portion and substantially parallel to the first sidewall portion. A plate body is formed and coupled to the channel body. The channel body has a single, one-piece construction with no welds formed using a subtractive manufacturing technique to limit optical effects associated with dimensional variation otherwise introduced into the channel body by welding.

In addition to one or more of the features described above, or as an alternative, further examples may include that one or more of the channel body and the plate body is formed using a wire sawing technique.

In addition to one or more of the features described above, or as an alternative, further examples may include forming one or more lateral slot within the channel body workpiece using a wire sawing technique, forming one or more first sidewall rib slot within the channel body workpiece using the wire sawing technique, and forming one or more second sidewall rib slot within the channel body workpiece using the wire sawing technique.

In addition to one or more of the features described above, or as an alternative, further examples may include that coupling the plate body to the channel body includes forming a first sidewall weld between the plate body and the first sidewall portion and forming a second sidewall weld between the plate body the second sidewall portion of the channel body.

In addition to one or more of the features described above, or as an alternative, further examples may include forming a shelf body using a wire sawing technique and coupling the shelf body to one or more of the channel body and the plate body.

In addition to one or more of the features described above, or as an alternative, further examples may include coupling an injection flange body to the channel body using an injection end weld and coupling an exhaust flange body to the channel body using an exhaust end weld.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a schematic view of a semiconductor processing system including a weldment in accordance with an example of the present disclosure, schematically showing a chamber arrangement including the weldment coupling a process fluid source to an exhaust source;

FIG. 2 is schematic view of the semiconductor processing system of FIG. 1 according to an example of the disclosure, schematically showing the process fluid source and a controller according to examples of the disclosure;

FIG. 3 is cross-sectional side view of the chamber arrangement of FIG. 1 according to an example of the disclosure, schematically showing a substrate seated within an interior of the weldment during deposition of a material layer onto a substrate and/or removal of material from the substrate according to the example;

FIG. 4 is an exploded view of the weldment of FIG. 1 according to an example of the disclosure, schematically showing a plate body and a shelf body exploded away from an channel body according to the example;

FIGS. 5A-5H illustrate a process flow diagram of operations for making a channel body for the weldment of FIG. 1 according to an example of the disclosure, schematically showing a wire sawing operation being used to form the channel body included in the weldment;

FIGS. 6A-6J illustrate a process flow diagram of operations for making a plate body for the weldment of FIG. 1 according to an example of the disclosure, schematically showing a wire sawing operation being used to form the plate body included in the weldment;

FIGS. 7A-7H illustrate a process flow diagram of operations for making a shelf body included in the weldment of FIG. 1 according to an example of the disclosure, schematically showing a wire sawing operation being used to form the shelf body included in the weldment;

FIG. 8 to FIG. 11 are side elevation and plan views of the weldment of FIG. 1 according to an example of the disclosure, schematically showing welds coupling the plate body and the shelf body to the channel body according to the example;

FIG. 12 is a block diagram of a method making a weldment in accordance with the present disclosure, schematically showing operations of the method according to an illustrative and non-limiting example of the method;

FIG. 13 and FIG. 14 are block diagrams of portions of the method of FIG. 12 according to an example of the disclosure, schematically showing operations for making a plate portion with rib portion and sidewall portions with rib portions of the channel body included in the weldment using a wire sawing technique;

FIG. 15 is a block diagram of a portion of the method of FIG. 12 according to an example of the disclosure, schematically showing operations for making a plate body included in the weldment using a wire sawing technique; and

FIG. 16 is a block diagram of a portion of the method of FIG. 12 according to an example of the disclosure, schematically showing operations for making a shelf body included in the weldment using a wire sawing technique.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

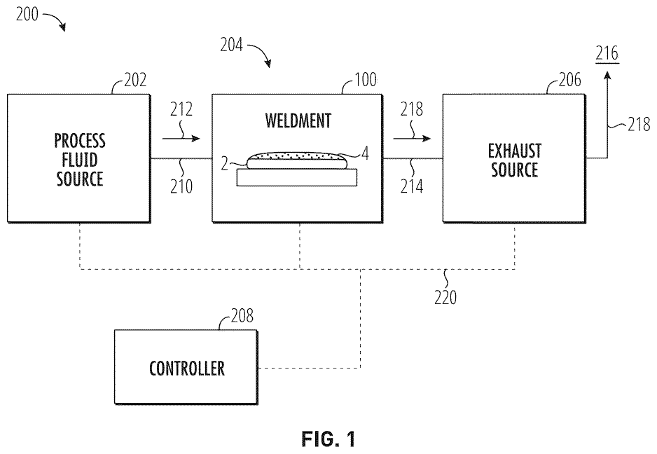

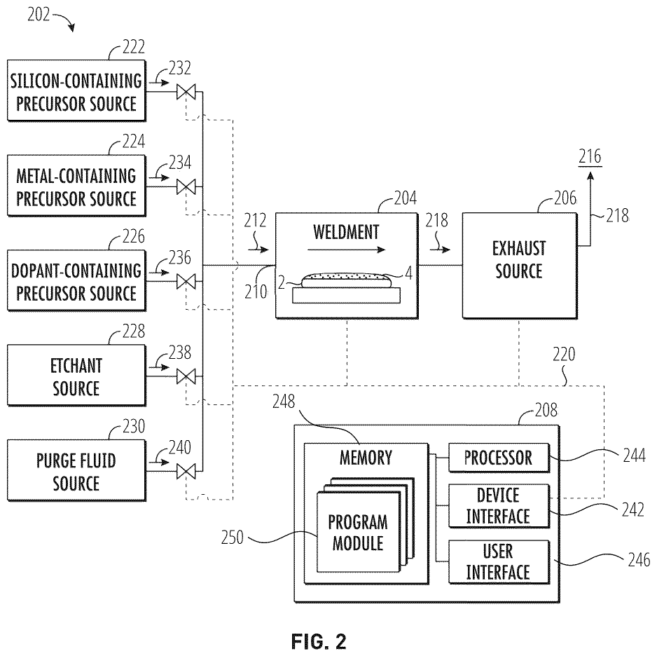

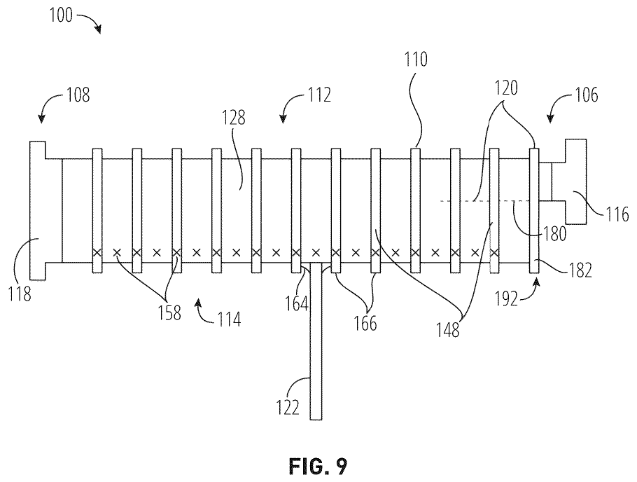

Reference will now be made to the drawings wherein like reference numerals identify similar structural features or aspects of the subject disclosure. For purposes of explanation and illustration, and not limitation, a partial view of an example of a weldment in accordance with the present disclosure is shown in FIG. 1 and is designated generally by reference character 100. Other examples of weldments, chamber arrangements and semiconductor processing systems including weldments, and methods of making weldments for chamber arrangements and semiconductor processing systems in accordance with the present disclosure, or aspects thereof, are provided in FIG. 2 to FIG. 16, as will be described. The systems and methods of the present disclosure may be used to make weldments for chamber arrangements in semiconductor processing systems, such as ceramic weldments employed to deposit epitaxial silicon-containing material layers onto substrates using chemical vapor deposition techniques, though the present disclosure is not limited to an particular type of material layer deposition technique nor to weldments employed in chamber arrangements for semiconductor processing systems in general.

Referring to FIG. 1, a semiconductor processing system 200 including the weldment 100 is shown. The semiconductor processing system 200 generally includes a process fluid source 202, a chamber arrangement 204 including the weldment 100, an exhaust source 206, and a controller 208. The process fluid source 202 is coupled to the chamber arrangement 204 by a process fluid supply conduit 210 and is configured to provide a flow of a process fluid 212 to the chamber arrangement 204. The weldment 100 is coupled to the exhaust source 206 by an exhaust conduit 214 and is configured to contact a substrate 2 supported within the weldments under environmental conditions, e.g., temperature and pressure, selected to cause a material layer 4 to deposit onto the substrate 2. The exhaust source 206 is in fluid communication with an external environment 216 outside of the semiconductor processing system 200, is configured to maintain a reduced pressure within the weldment 100 (less than about 760 Torr, or less than about 700 Torr, or less than about 500 Torr, or less than about 200 Torr, or between about 0.1 Torr and about 700 Torr), and is configured to communicate a flow of residual process fluid and/or reaction products 218 issued by the chamber arrangement 204 to the external environment 216 outside of the chamber arrangement 204. The controller 208 is operatively associated with one or more of the process fluid source 202, the chamber arrangement 204 and/or the exhaust source 206 to control deposition of the material layer 4 onto the substrate 2. Operative association may be through a wired or wireless link 220 communicatively coupling the controller 208 to one or more of the aforementioned modules of the semiconductor processing system 200.

As used herein the term “substrate” may refer to any underlying material or materials, including any underlying material or materials that may be modified, or upon which, a device, a circuit, or a film may be formed. A substrate may be continuous or non-continuous; rigid or flexible; solid or porous; and combinations thereof. A substrate may be in any form such as (but not limited to) a powder, a plate, or a workpiece. A substrate in the form of a plate may include a wafer in various shapes and sizes, for example, including 300-millimeter wafers. A substrate may be formed from semiconductor materials, including, for example, silicon (Si), silicon-germanium (SiGe), silicon oxide (SiO₂), gallium arsenide (GaAs), gallium nitride (GaN) and silicon carbide (SiC). A substrate may include a pattern or may be unpatterned, such as a so-called blanket-type substrate. As examples, substrates in the form of a powder may have applications for pharmaceutical manufacturing. A porous substrate may including one or more polymers. Examples of workpieces may include medical devices (for example, stents and syringes), jewelry, tooling devices, components for battery manufacturing (for example, anodes, cathodes, or separators) or components of photovoltaic cells, etc. A continuous substrate may extend beyond the bounds of a process chamber where a deposition process occurs. In some processes, a continuous substrate may move through the process chamber such that the process continues until the end of the substrate is reached. A continuous substrate may be supplied from a continuous substrate feeding system to allow for manufacture and output of the continuous substrate in any appropriate form. Non-limiting examples of continuous substrates may include sheets, non-woven films, rolls, foils, webs, flexible materials, bundles of continuous filaments or fibers (for example, ceramic fibers or polymer fibers). A continuous substrate may also comprise a carrier or sheet upon which one or more non-continuous substrate is mounted.

With reference to FIG. 2, the process fluid source 202 and the controller 208 are shown according to examples of the present disclosure. In the illustrated example the process fluid source 202 includes a silicon-containing precursor source 222, a metal-containing precursor source 224, a dopant-containing precursor source 226, and etchant source 228, and a carrier/purge fluid source 230. The silicon-containing precursor source 222 includes a silicon-containing material layer precursor 232, is coupled to the chamber arrangement 204 by the process fluid supply conduit 210, and is configured to provide a flow of the silicon-containing material layer precursor 232 to the chamber arrangement 204, for example to deposit an epitaxial silicon-containing material layer 4 onto the substrate 2. In this respect it is contemplated that the silicon-containing precursor source 222 may be coupled to the process fluid supply conduit 210 by a flow control device, such as a flow control valve and/or a mass flow controller (MFC) device, operably associated with the controller 208. In certain examples the silicon-containing material layer precursor 232 may include (or consist of or consist essentially of) a non-halogenated silicon-containing material layer precursor. Examples of suitable non-halogenated silicon-containing material layer precursors include silane, disilane, and trisilane as a higher order non-halogenated silicon-containing material layer precursors. In accordance with certain examples, the silicon-containing material layer precursor may include (or consist of or consist essentially of) a halogenated silicon-containing material layer precursor. Examples of suitable halogenated silicon-containing material layer precursors include dichlorosilane and trichlorosilane as well as higher order halogenated silicon-containing material layer precursors.

The metal-containing precursor source 224 is similar to the silicon-containing precursor source 222 and is additionally configured to provide a flow of a metal-containing material layer precursor 234 to the chamber arrangement 204. In this respect it is contemplated that the metal-containing precursor source 224 may include the metal-containing material layer precursor 234, such as an alloying material layer constituent, to deposit a metal-containing material layer 4 onto the substrate 2. In further respect, the metal-containing precursor source 224 may be coupled to the chamber arrangement 204 by the process fluid supply conduit 210, for example through a flow control valve and/or an MFC device, operably associated with the controller 208 to communicate the flow of the metal-containing material layer precursor 234 to the chamber arrangement 204. In certain examples the metal-containing material layer precursor 234 may include germanium (Ge), such as in examples where the metal-containing material layer 4 includes (or consist of or consists essentially of) silicon germanium (SiGe). Examples of suitable germanium-containing material layer precursors include germane (GeH₄), germanium tetrachloride (GeCl₄), and digermane (Ge₂H₆). In accordance with certain examples, the metal-containing material layer precursor 234 may include gallium (Ga), aluminum (Al), indium (In), or scandium (Sc), which may be included in the metal-containing material layer 4 deposited onto the substrate 2. In such examples the material layer 4 may include (or consist of or consist essentially of) gallium nitride (GaN), aluminum nitride (AlN), indium nitride (InN), or scandium nitride (ScN). Examples of suitable metal-containing material layer precursors employed in the deposition of such material layers include metal alkyls such as trimethylgallium (Ga(CH₃)₃), trimethylaluminum (Al(CH₃)₃), trimethylindium (In(CH₃)₃), or trimethyl scandium (Sc(CH₃)₃); halide like gallium trichloride (GaCl₃), aluminum trichloride (AlCl₃), indium trichloride (InCl₃), or scandium chloride (ScCl₃); and hydrides such as gallium hydride (GaH₃), aluminum hydride (AlH₃), indium hydride (InH₃), or scandium hydride (ScH₃). As will be appreciated by those of skill in the art in view of the present disclosure, other metal-containing material layer precursor and remain within the scope of the present disclosure.

The dopant-containing precursor source 226 may be similar to the silicon-containing precursor source 222 and is additionally configured to provide a flow of a dopant-containing material layer precursor 236 to the chamber arrangement 204. It is contemplated that the dopant-containing precursor source 226 may include the dopant-containing material layer precursor 236, and that the dopant-containing precursor source 226 may be coupled to the chamber arrangement 204 through a flow metering valve and/or an MFC device operably associated with the controller 208. In certain examples the dopant-containing material layer precursor 236 may include an n-type dopant, such as arsenic (As) and/or phosphorous (P), the material layer 4 deposited onto the substrate 2 being a doped material layer. In such examples the dopant-containing material layer precursor 236 may include one or more of arsine (AsH₃) and phosphine (PH₃). In accordance with certain examples, the dopant-containing material layer precursor 236 may include a p-type, such as phosphorous. Examples of suitable phosphorous-containing material layer precursors including diborane (B₂H₆). As will be appreciated by those of skill in the art in view of the present disclosure, the material layer 4 may be an n-type or p-type doped material layer in such examples.

It is contemplated that the etchant source 228 and the carrier/purge fluid source 230 may be configured to communicate a flow of an etchant 238 and a carrier/purge fluid 240 (e.g., a carrier/purge gas) to the chamber arrangement 204. In this respect it is contemplated that the etchant source 228 may include the etchant 238 and be coupled to the chamber arrangement 204 by the process fluid supply conduit 210 through a flow metering device, such as a metering valve and/or an MFC device, operably associated with the controller 208. In certain examples the etchant 238 may include (or consist of or consist essentially of) a chlorine-containing etchant. Examples of suitable chlorine-containing etchants include hydrochloric (HCl) acid, chlorine (Cl₂) gas, and/or chlorine radicals. In accordance with certain examples, the etchant 238 may include a fluorine-containing etchant. Examples of suitable fluorine-containing etchants include hydrofluoric (HF) acid, fluorine (F₂) gas, and fluorine radicals. It is contemplated that the etchant source 228 may further configured to communicate the etchant 238 to the chamber arrangement 204 independently of the aforementioned material layer precursors, or intermixed with one or more of the aforementioned material layer precursors, as appropriate for the material layer 4 being deposited onto the substrate 2 within the chamber arrangement 204.

The carrier/purge fluid source 230 may be similar to the etchant source 228 and additionally be configured to communicate the carrier/purge fluid 240 to the chamber arrangement 204. In this respect the carrier/purge fluid source 230 may be configured to communicate the carrier/purge fluid independently to the chamber arrangement 204 (e.g., as a purge gas) and/or intermixed with one or more of the aforementioned material layer precursors as well as the etchant 238 (e.g., as a carrier gas and/or as a diluent). Examples of suitable carrier/purge fluids include hydrogen (H₂) gas, nitrogen (N₂) gas, noble gases like argon (Ar) and helium (He), and mixtures including one or more of the aforementioned fluids.

The controller 208 may include a device interface 242, a processor 244, a user interface 246, and a memory 248. The device interface 242 couples (e.g., communicatively couples) the processor 244 to one or more of the process fluid source 202, the chamber arrangement 204, and the exhaust source 206, for example through the wired or wireless link 220. The processor 244 is operatively connected to the user interface 246, for example to provide a user output therethrough and/or receive a user input therefrom, and is disposed in communication with the memory 248. It is contemplated that the memory 248 in turn have a plurality of program modules 250 recorded thereon containing instructions that, when read by the processor 244, cause the processor 244 to execute certain operations. Among the operations are operations of a material layer deposition method, for example a silicon-containing material layer deposition method and/or a metal-containing material layer deposition method. Although shown and described herein as having a specific arrangement, it is to be understood and appreciated that the controller 208 may have different architectures and /r arrangements in other examples, e.g., a distributed computing architecture, and remain within the scope of the present disclosure.

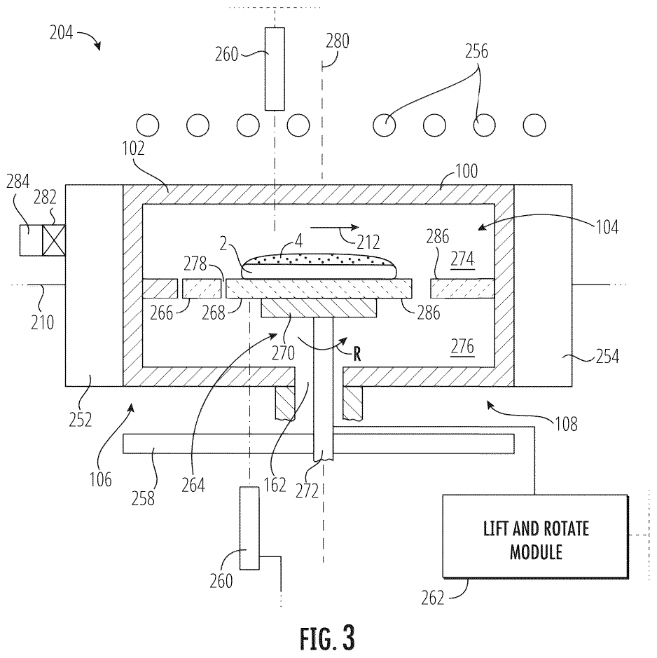

With reference to FIG. 3, the chamber arrangement 204 is shown according to an example the present disclosure. In the illustrated example the chamber arrangement 204 is configured as a cold wall-type gas phase reactor (e.g., a reactor wherein precursor and/or reactants are introduced into the reactor in a gaseous state) and in this respect include an injection manifold 252, an exhaust manifold 254, an upper heater element array 256, a lower heater element array 258, one or more non-contact temperature sensor 260, and a lift and rotate module 262. Although shown and described herein as including certain elements, it is to be understood and appreciated that the chamber arrangement 204 may include additional elements and/or omit elements shown and described herein in other examples and remain within the scope of the present disclosure.

The weldment 100 is formed from a transparent material 102, for example a material transparent to electromagnetic radiation within an infrared waveband, and has a hollow interior 104. The weldment 100 further extends between an injection end 106 and a longitudinally opposite exhaust end 108 and contains therein a process kit 264 including a divider 266, a substrate support 268, a support member 270, and a shaft member 272. The injection manifold 252 abuts the injection end 106 of the weldment 100, couples the process fluid supply conduit 210 to the weldment 100, and fluidly couples the process fluid source 202 (shown in FIG. 1) to the interior 104 of the weldment 100. The exhaust manifold 254 abuts the exhaust end 108 of the weldment 100 and is longitudinally separated from the injection manifold 252 by the weldment 100, couples the exhaust conduit 214 (shown in FIG. 1) to the weldment 100, and fluidly couples the interior 104 of the weldment 100 to the exhaust source 206 (shown in FIG. 2). In certain examples the transparent material 102 may include a ceramic material. Examples of suitable ceramic materials include fused silica, quartz, and sapphire. In accordance with certain examples, the weldment 100 may consist of or consist essentially of the transparent material 102. In illustrated example the weldment 100 is unribbed and in this respect has no external ribs. It is contemplated that the weldment 100 may be ribbed, for example to enable evacuation to relatively high interior-to-external environment pressure differentials (e.g., greater than 700 Torr), in other examples of the present disclosure.

The upper heater element array 256 is supported above the weldment 100, includes a plurality of upper heater elements configured to communicate electromagnetic radiation, e.g., electromagnetic radiation within an infrared waveband, into the interior 104 of the weldment 100 through the transparent material 102 to radiantly heat a substrate, e.g., the substrate 2, seated within the interior 104 of the weldment 100. In certain examples upper heater element array 256 may include a plurality of linear filament-type lamps each supported above the weldment 100, for example extending longitudinally between the injection end 106 and the exhaust end 108 of the weldment 100, and laterally spaced apart from one another between laterally opposite sides of the weldment 100. In accordance with certain examples, the upper heater element array 256 may include a plurality of linear filament-type lamps supported above the weldment 100 each extending laterally between laterally opposite sides of the weldment 100, the plurality of linear filament-type lamps longitudinally spaced apart from one another between the injection end 106 and the exhaust end 108 of the weldment 100. It is contemplated that the lower heater element array 258 may be similar to the upper heater element array 256, additionally be supported below the weldment 100, and further include a plurality of linear filament-type linear lamps angled (e.g., orthogonal) relative to the plurality of linear filament-type linear lamps of the upper heater element array 256. In certain examples either (or both) the upper heater element array 256 and the lower heater element array 258 may include bulb-type heater elements and remain within the scope of the present disclosure.

The divider 266 is seated within the interior 104 of weldment 100 and divides the interior 104 of the weldment 100 into an upper chamber 274 and a lower chamber 276. It is contemplated that the divider 266 further define a divider aperture 278 therethrough coupling the lower chamber 276 to the upper chamber 274, and that the substrate support 268 be supported within the divider aperture 278 therein for rotation R about a rotation axis 280. The support member 270 may be arranged within the lower chamber 276 of the weldment 100 and along the rotation axis 280, and fixed in rotation about the rotation axis 280 relative to the substrate support 268. The shaft member 272 may also be arranged (at least in part) within the lower chamber 276 of the weldment 100, be fixed in rotation about the rotation axis 280 relative to the support member 270, and protrude from the weldment 100 into the external environment 216 (shown in FIG. 1) outside of the weldment to operably couple the substrate support 268 to the lift and rotate module 262. It is contemplated that the lift and rotate module 262 be configured to seat and unseat the substrate 2 from the substrate support 268, such as for loading and unloading singular substrates from the weldment 100 in cooperation with a gate valve 282 and a substrate transfer robot 284, and the that the lift and rotate module 262 further be configured to rotate the substrate support 268 with the substrate 2 seated thereon during deposition of the material layer 4 thereon using the process fluid 212. It is further contemplated that either (or both) the divider 266 and the substrate support 268 be formed from an opaque material 286, for example a material opaque to infrared within an infrared waveband, the substrate support 268 including a susceptor structure in certain examples of the disclosure, and the non-contact temperature sensor 260 (e.g., a pyrometer) be optically coupled to structure(s) within the interior 104 of the weldment 100 to control temperature of the substrate 2 during deposition of the material layer 4 onto the substrate 2 and/or during removal of material therefrom. Examples of suitable opaque materials include carbonaceous materials, such as pyrolytic carbon and graphite, as well as ceramic materials such as silicon carbide.

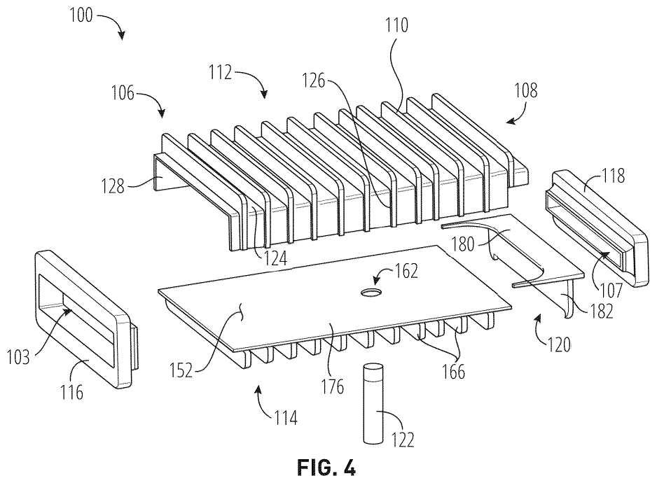

With reference to FIG. 4 and FIG. 8 to FIG. 11, the weldment 100 is shown according to an example of the disclosure. In the illustrated example the weldment 100 has a plurality of external ribs 110 extending laterally thereabout and longitudinally spaced apart between the injection end 106 and the exhaust end 108 of weldment 100 and is formed as an assembly of a limited number of discrete piece parts. As shown in FIG. 4, it is contemplated that the weldment 100 include a limited number of discrete piece parts assembled into an integrated end item (e.g. assembled by welds) and in this respect includes a channel body 112, a plate body 114, an injection flange body 116, an exhaust flange body 118, a shelf body 120, and a tubulation body 122. Advantageously, limiting the number of discrete piece parts included in the weldment 100 may simplify manufacture of the weldment 100 and/or reduce cost of the weldment 100, for example by limiting the number of post-welding operation annealing operations required to stress relieve the weldment 100. In certain examples the weldment 100 may have fewer than 60 pieces, or less than 35 pieces, or even less than 10 pieces, such as between 40 pieces and 6 discrete pieces coupled to one another by welds.

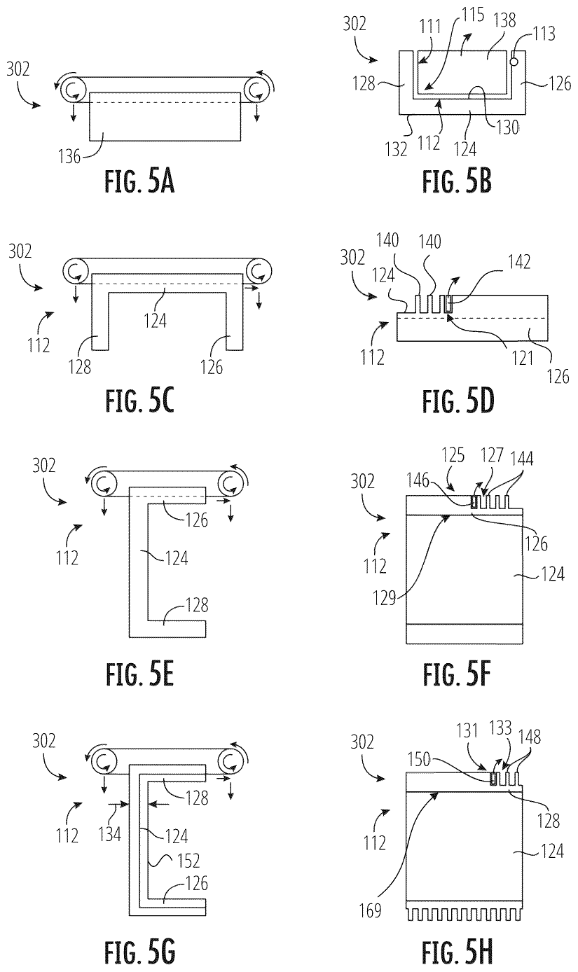

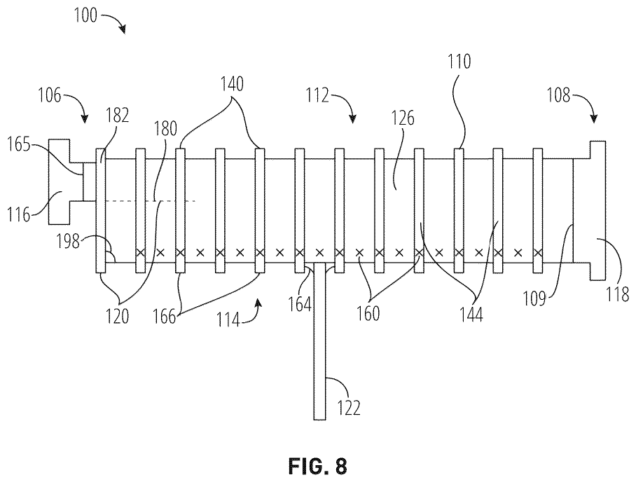

As shown in FIG. 8 to FIG. 11, it is contemplated that the channel body 112 may be formed of a single, one-piece body, from the transparent material 102 (shown in FIG. 3) and have a plate portion 124, a first sidewall portion 126, and a second sidewall portion 128. The plate portion 124 of the channel body 112 may be generally rectangular in shape and in this respect may extend longitudinally between the injection end 106 and the exhaust end 108 of the weldment 100 and laterally between the first sidewall portion 126 and the second sidewall portion 128 of the weldment 100. It is further contemplated that the plate portion 124 of the channel body 112 have an interior surface 130 (shown in FIG. 5B) and an exterior surface 132 (shown in FIG. 5B) separated from one another by a thickness 134 (shown in FIG. 5G) of the plate portion 124, and may extend both longitudinally between the injection end 106 and the exhaust end 108 of the weldment 100 as well as laterally between the first sidewall portion 126 and second sidewall portion 128 of the channel body 112.

The first sidewall portion 126 of the channel body 112 extends from the interior surface 130 (shown in FIG. 5B) of the plate portion 124 of the channel body 112. The first sidewall portion 126 may further be substantially orthogonal relative to the interior surface 130 of the channel body 112 and longitudinally span the injection end 106 (shown in FIG. 3) and the exhaust end 108 (shown in FIG. 3) of the weldment 100. The second sidewall portion 128 of the channel body 112 is similar to the first sidewall portion 126 of the channel body 112, is additionally separated from the first sidewall portion 126 of the channel body 112 by the interior surface 130 of the plate portion 124 of the channel body 112, and may be substantially parallel to the first sidewall portion 126 of the channel body 112.

As shown in FIGS. 5A-5H, it is contemplated that the single, one-piece body of the channel body 112 may have an unwelded construction. In this respect the plate portion 124, the first sidewall portion 126, and the second sidewall portion 128 of the channel body 112 may formed from a singular, one-piece channel body workpiece 136 (shown in FIG. 5A) formed from the transparent material 102 (shown in FIG. 3). In further respect it is contemplated that each of the plate portion 124, the first sidewall portion 126, and the second sidewall portion 128 of the channel body 112 be formed from the one-piece channel body workpiece 136 using a subtractive manufacturing technique. Advantageously, this avoids employing welding the channel body 112 to couple either (or both) the first sidewall portion 126 and the second sidewall portion 128 of the channel body 112 to the plate portion 124 of the channel body 112.

In certain examples one or more wire sawing operation (e.g., depicted by the dotted line in FIG. 5A) may be employed to separate a channel body slab 138 of transparent material from the singular, one-piece channel body workpiece 136, such as by defining one or more longitudinal slot within the singular, one-piece channel body workpiece 136. In accordance with certain examples, the subtractive manufacturing technique may include a boring or drilling operation. In either of such operations such examples the wire sawing operation and/or the boring or drilling operation may be followed by machining operation to interior-facing surfaces of one or more of the plate portion 124, the first sidewall portion 126, and the second sidewall portion 128. Advantageously, forming the channel body 112 with a single, one-piece construction may limit (or eliminate) distortion otherwise imparted into the channel body 112 by welding either (or both) a discrete first sidewall body and a second sidewall body to a discrete plate body to form the weldment 100. As will be appreciated by those of skill in the art in view of the present disclosure, limiting distortion associated with welding may limit (or eliminate) optical effects of such distortion on the exterior surface 132 of the channel body 112, limiting temperature variation and associated cross-substrate thickness variation within material layers deposited onto substrates within the weldment 100, for example within the material layer 4 (shown in FIG. 3) deposited onto the substrate 2 (shown in FIG. 3) within the weldment 100.

With continuing reference to FIG. 8 to FIG. 11, it is contemplated that the plate portion 124 of the channel body 112 may have a plurality of channel body rib portions 140. In such examples the plurality of channel body rib portions 140 may extend from the exterior surface 132 of the plate portion 124 of the channel body 112. The plurality of channel body rib portions 140 may laterally span the plate portion 124 of the channel body 112 and be longitudinally spaced apart from one another between the injection end 106 and the exhaust end 108 of the channel body 112. The plurality of channel body rib portions 140 may further be substantially parallel to one another and/or substantially orthogonal relative to either (or both) the first sidewall portion 126 and the second sidewall portion 128 of the channel body 112. In the illustrated example the plurality of channel body rib portions 140 includes twelve (12) channel body rib portions. As will be appreciated by those of skill in the art in view of the present disclosure, the plate portion 124 of the channel body 112 may have fewer or additional channel body rib portions 140 than shown and described herein in other examples and remain within the scope of the present disclosure.

In such examples wherein the channel body 112 has a unwelded single, one piece construction the plurality of channel body rib portions 140 may also be formed from the singular, one-piece channel body workpiece 136 (shown in FIG. 5A), for example using the subtractive manufacturing technique and without the employment of welds to couple one or more of the plurality of channel body rib portions 140 to the plate portion 124 of the channel body 112. In certain examples a wire sawing operation (e.g., as shown in FIG. 5C) may be employed to separate a plate portion rib slab (e.g., channel body lateral rib slab 142 shown in FIG. 5D) of transparent material from the singular, one-piece channel body workpiece 136, such as by defining one or more lateral slot within the singular, one-piece channel body workpiece 136. In accordance with certain examples, the subtractive manufacturing technique may include a boring or drilling operation to define the plurality of channel body rib portions 140. In such examples the wire sawing operation and/or the boring or drilling operation may be followed by machining operation, for example to defines faces and/or chamfers on the plurality of channel body rib portions 140 of the channel body 112. Advantageously, forming the plurality of channel body rib portions 140 as part of the single, one-piece construction may limit (or eliminate) distortion otherwise imparted into the channel body 112 by welding either (or both) a discrete rib bodies to a discrete plate body to integrally form the weldment 100 as an assembly of discrete piece parts. As above, limiting distortion otherwise associated with welding discrete rib bodies to a plate body may limit (or eliminate) optical effects of such distortion, limiting temperature variation and associated cross-substrate thickness variation within material layers deposited onto substrates within weldment 100, for example within the material layer 4 (shown in FIG. 3) deposited onto the substrate 2 (shown in FIG. 3) while supported within the weldment 100.

In certain examples the plate portion 124 of the channel body 112 may have a plurality of first sidewall rib portions 144. In such examples the plurality of first sidewall rib portions 144 may extend (e.g., protrude) laterally from the first sidewall portion 126 of the channel body 112 and in a directly opposite the second sidewall portion 128 of the channel body 112. It is contemplated that the plurality of first sidewall rib portions 144 may further span the first sidewall portion 126 of the channel body 112 (e.g., vertically relative gravity) and be longitudinally spaced apart from one another between the injection end 106 and the exhaust end 108 of the channel body 112. It is contemplated that the plurality of first sidewall rib portions 144 may be substantially parallel to one another and/or substantially orthogonal relative to either (or both) the plate portion 124 of the channel body 112, that respective ones of the plurality of first sidewall rib portions 144 may share longitudinal positions with respective ones of the plurality of channel body rib portions 140, and that respective ones of the plurality of first sidewall rib portions 144 may extend continuously with the respective ones of the plurality of channel body rib portions 140. In the illustrated example the plurality of first sidewall rib portions 144 is equivalent in number to the plurality of channel body rib portions 140, the channel body 112 having twelve (12) first sidewall rib portions in certain examples of the disclosure. As will be appreciated by those of skill in the art in view of the present disclosure, the first sidewall portion 126 may have fewer or additional first sidewall rib portions 144 than shown and described herein in other examples and remain within the scope of the present disclosure.

In such examples wherein the channel body 112 has the unwelded single, one piece construction, the plurality of first sidewall rib portions 144 may additionally be formed from the singular, one-piece channel body workpiece 136 (shown in, e.g., FIGS. 5A, 5F). In this respect it is contemplated that the that plurality of first sidewall rib portions 144 may be formed using a subtractive manufacturing technique, for example a wire sawing technique (shown in FIG. 5E) and without the employment of welds to couple one or more of the plurality of first sidewall rib portions 144 to the first sidewall portion 126 of the channel body 112. In this respect it is contemplated that the wire sawing operation may be employed to separate a first sidewall rib slab 146 (shown in FIG. 5F) of transparent material from the singular, one-piece channel body workpiece 136, such as by defining one or more vertical slot within the singular, one-piece channel body workpiece 136. In accordance with certain examples, the subtractive manufacturing technique may include a boring or drilling operation to define the plurality of first sidewall rib portions 144. In such examples the wire sawing operation and/or the boring or drilling operation may be followed by machining operation, for example to defines faces and/or chamfers on the plurality of first sidewall rib portions 144. Advantageously, forming the plurality of first sidewall rib portions 144 as part of the single, one-piece construction of the channel body 112 may limit lateral width of the weldment 100, for example by eliminating the debit otherwise included in the factor of safety of the weldment 100 required to account for variation in welds otherwise used to couple discrete first sidewall ribs to a weldment. As will be appreciated by those of skill in the art in view of the present disclosure, this enables the plurality of first sidewall rib portions 144 to protrude laterally from the first sidewall portion 126 by a smaller distance than welded first sidewall rib bodies, reducing footprint and space occupied by the weldment 100, and by extension the chamber arrangement 204 (shown in FIG. 1) including the weldments 100.

In certain examples, the second sidewall portion 128 of the channel body 112 may have a plurality of second sidewall rib portions 148. In such examples the plurality of second sidewall rib portions 148 may extend (e.g., protrude) laterally from the second sidewall portion 128 of the channel body 112 and in a directly opposite the first sidewall portion 126 of the channel body 112. It is contemplated that the plurality of second sidewall rib portions 148 may further span the second sidewall portion 128 of the channel body 112 (e.g., vertically relative to gravity) and be longitudinally spaced apart from one another between the injection end 106 and the exhaust end 108 of the channel body 112. It is also contemplated that the plurality of second sidewall rib portions 148 may be substantially parallel to one another and/or substantially orthogonal relative to either (or both) the plate portion 124 of the channel body 112, that respective ones of the plurality of second sidewall rib portions 148 may share longitudinal positions with respective ones of the plurality of channel body rib portions 140, and that respective ones of the plurality of second sidewall rib portions 148 may extend continuously with the respective ones of the plurality of channel body rib portions 140 and respective ones of the plurality of first sidewall rib portions 144. In the illustrated example the plurality of second sidewall rib portions 148 is equivalent in number to the plurality of channel body rib portions 140 and the plurality of first sidewall rib portions 144, the channel body 112 having twelve (12) second sidewall rib portions 148 in certain examples of the disclosure. As will be appreciated by those of skill in the art in view of the present disclosure, the second sidewall portion 128 may have fewer or additional second sidewall rib portions 148 in other examples and remain within the scope of the present disclosure.

In such examples wherein the channel body 112 has the unwelded single, one piece construction, the plurality of second sidewall rib portions 148 further be formed from the singular, one-piece channel body workpiece 136 (shown in FIG. 5H), for example using the subtractive manufacturing technique such as a wire sawing technique (shown in FIG. 5G). In this respect it is contemplated that no welds may be employed to couple one or more of the plurality of second sidewall rib portions 148 to the second sidewall portion 128 of the channel body 112. The wire sawing operation may be employed to separate a second sidewall rib slab 150 of transparent material from the singular, one-piece channel body workpiece 136, such as by defining one or more vertical slot within the singular, one-piece channel body workpiece 136. In accordance with certain examples, the subtractive manufacturing technique may include a boring or drilling operation to define the plurality of second sidewall rib portions 148. In such examples the wire sawing operation and/or the boring or drilling operation may be followed by machining operation, for example to defines faces and/or chamfers on the plurality of second sidewall rib portions 148. Advantageously, forming the plurality of second sidewall rib portions 148 as portions of the single, one-piece construction of the channel body 112 may further limit lateral width of the weldment 100, as explained above, also enabling the plurality of first sidewall rib portions 144 to protrude laterally from the second sidewall portion 128 of the weldments 100 by a smaller distance than otherwise required by welded first sidewall rib bodies, further reducing footprint and space occupied by the weldment 100 and by extension the chamber arrangement 204 (shown in FIG. 1) including the weldments 100. In certain examples of the present disclosure the reduction in lateral width may enable twinning the weldment 100 and an additional weldment 100 in a dual chamber module hosted by a cluster-type platform wherein slit spacing on the substrate transfer chamber otherwise precludes twinning (e.g., arrangement two longitudinally extending cross-flow reactors side-by-side with one another) the weldment 100 with another weldment.

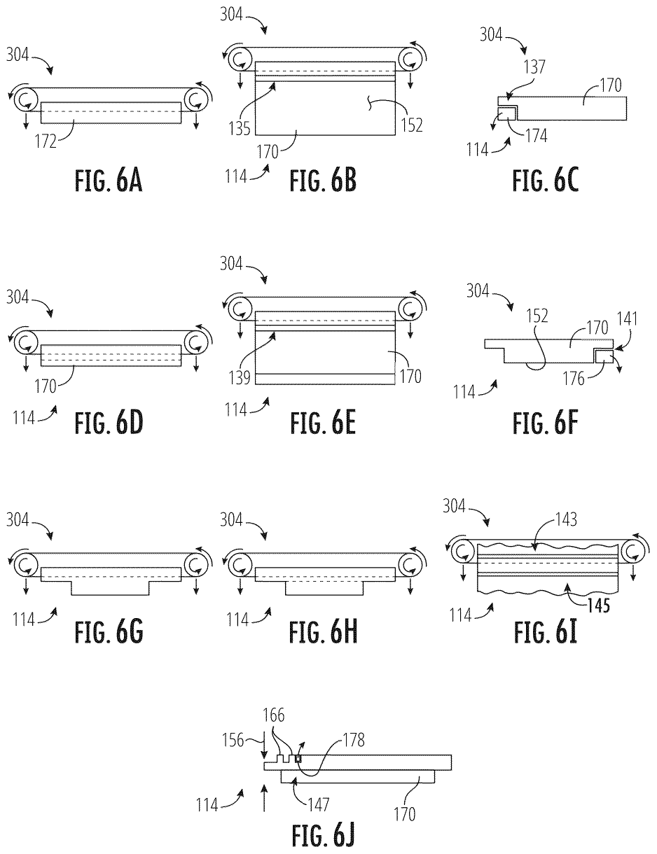

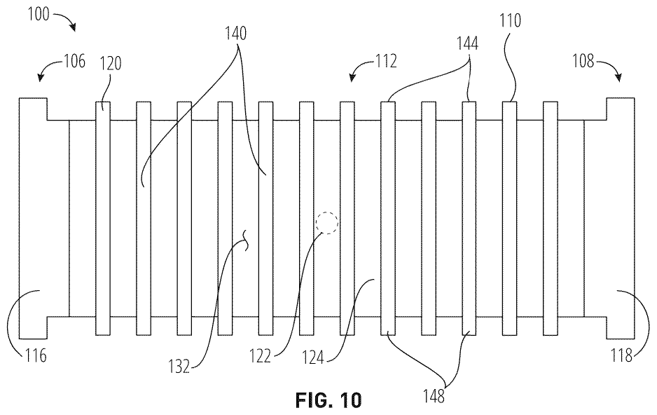

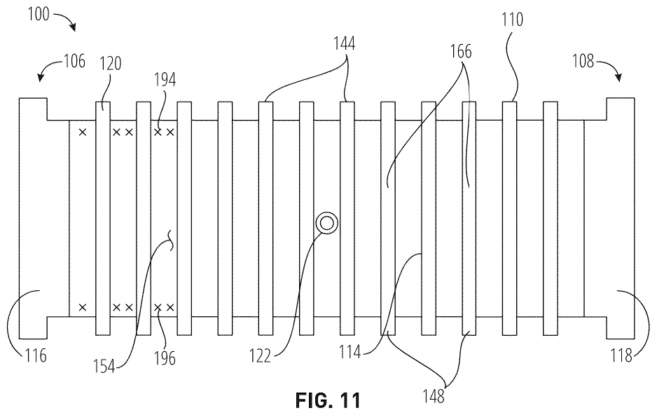

Referring once again to FIG. 4, it is contemplated that the plate body 114 be formed as a single, one-piece discrete piece part from a transparent material, for example the transparent material 102 (shown in FIG. 3). The plate body 114 may further correspond generally in shape and dimension to the plate portion 124 (shown in FIG. 10) of the channel body 112. In this respect it is contemplated that the plate body 114 may be generally rectangular in shape, have an interior surface 152 and an exterior surface 154 (shown in FIG. 11) separated from the interior surface 152 by a thickness 156 (shown in FIG. 6J) of the plate body 114, and be registered to the channel body 112 such that the channel body 112 overlies the plate body 114. It is contemplated that the plate body 114 be separated (e.g., spaced apart) from the plate portion 124 of the channel body 112 by the first sidewall portion 126 and the second sidewall portion 128 of the channel body 112 such that the interior 104 (shown in FIG. 3) of the weldment 100 is bounded by both the interior surface 152 of the plate body 114 and the interior surface 152 (shown in FIG. 5G) of the plate portion 124 of the channel body 112.

With continuing reference to FIG. 8 to FIG. 11, it is contemplated that the plate body 114 be coupled to the channel body 112 by a first sidewall weld 158 and a second sidewall weld 160 coupling the plate body 114 to the first sidewall portion 126 and the second sidewall portion 128 of the channel body 112. In certain examples first sidewall weld 158 may extend longitudinally along the first sidewall portion 126 of the channel body 112, the first sidewall weld 158 longitudinally spanning a longitudinal length of the channel body 112 between the injection end 106 of the weldment 100 and the exhaust end 108 of the weldment 100. In such examples the second sidewall weld 160 may be similar to the first sidewall weld 158, the second sidewall weld 160 similarly spanning a longitudinal length of the channel body 112 between the injection end 106 and the exhaust end 108 of the channel body 112, the second sidewall weld 160 separated from the first sidewall weld 158 by the plate body 114. As used herein the term “weld” means a thermal bond, link or structure that joins two elements through a process that involves a softening or melting of a ceramic material within at least one of the elements such that the materials of the elements are secured to each other when cooled, the welded elements thereby being structurally secured to one another when cooled.

In certain examples the plate body 114 may define therethrough a passthrough 162 (shown in FIG. 3). The passthrough 162 may extend between the interior surface 152 and the exterior surface 154 through the thickness 156 of the plate body 114, the passthrough 162 extending the interior 104 of the weldment 100 to include an environment separated from the channel body 112 by the plate body 114. In this respect it is contemplated that the passthrough 162 be configured to received therethrough the shaft member 272 (shown in FIG. 3), the passthrough 162 sized and dimensioned such that the shaft member 272 may rotate therein about the rotation axis 280 (shown in FIG. 3) within the passthrough 162. In accordance with certain examples, the tubulation body 122 may extend about the passthrough 162, depend from the plate body 114 of the weldment 100, and be coupled to the exterior surface 154 of the plate body 114 by a tubulation body weld 164. In this respect it is contemplated that the tubulation body 122 may at least in part envelope the shaft member 272.

In certain examples the plate body 114 have a plurality of plate body rib portions 166. In such examples the plurality of plate body rib portions 166 may extend from the exterior surface 154 of the plate body 114 and in a direction opposite the interior surface 152 (shown in FIG. 4) of the plate body 114. It is contemplated that the plurality of plate body rib portions 166 may laterally span the plate body 114 and be longitudinally spaced apart from one another between the injection end 106 and the exhaust end 108 of the channel body 112. The plurality of plate body rib portions 166 may further be substantially parallel to one another and/or substantially orthogonal relative to either (or both) the first sidewall portion 126 and the second sidewall portion 128 of the channel body 112. It is further contemplated that the plurality of plate body rib portions 166 may protrude laterally from the first sidewall portion 126 and the second sidewall portion 128 of the channel body 112. In certain examples the plurality of plate body rib portions 166 may correspond in number to the plurality of channel body rib portions 140, each of the plurality of plate body rib portions 166 underlying a respective one of the plurality of channel body rib portions 140 and coupled thereto by individual ones of the plurality of first sidewall rib portions 144 and the plurality of second sidewall rib portions 148. In accordance with certain examples, the plurality of plate body rib portions 166 may be fewer in number than the plurality of channel body rib portions 140, for example to facilitate assembly of the shelf body 120 into the weldment 100. In the illustrated example the plurality of plate body rib portions 166 includes eleven (11) plate body rib portions. As will be appreciated by those of skill in the art in view of the present disclosure, the plate body 114 may have fewer or additional plate body rib portions 166 than shown and described herein in other examples and remain within the scope of the present disclosure.

With reference to FIG. 6A-J, it is contemplated that the plate body 114 have an unwelded single, one piece construction. In such examples the plurality of plate body rib portions 166 and a plate portion 170 of the plate body 114 may be formed from a singular, one-piece plate body workpiece 172. In this respect it is contemplated that the plate portion 170 and the plurality of plate body rib portions 166 be formed using a subtractive manufacturing technique and without the employment of welds to couple discrete pieces parts, to form the plate body 114. In certain examples the subtractive manufacturing technique may include a wire sawing technique, for example as shown in FIGS. 6A-C and 6D-F, to separate a first plate body longitudinal slab 174 (shown in FIG. 6C) and a second plate body longitudinal slab 176 (shown in FIG. 6F) from the plate body workpiece 172.

It is contemplated that a subtractive manufacturing process may be employed to define the plurality of plate body rib portions 166. In this respect it is contemplated that one or more wire sawing technique, such as shown in FIGS. 6G-I), may be employed to separate a plate portion rib slab 178 of transparent material from the plate body workpiece 172 to define the plurality of plate body rib portions 166. In such examples one or more lateral slot may be defined within the plate body workpiece 172, the one or more lateral slot extending laterally across the singular, one-piece plate body workpiece 172. In further respect, it is also contemplated a boring or drilling operation to define the plurality of plate body rib portions 166. In either example the wire sawing operation and/or the boring or drilling operation may be followed by machining operation, for example to defines faces and/or chamfers on the plurality of plate body rib portions 166 of the plate body 114. Advantageously, forming the plurality of plate body rib portions 166 as part of the single, one-piece construction with the plate portion 170 of the plate body 114 may limit (or eliminate) distortion otherwise imparted into the plate body 114 by welding either (or both) a discrete rib bodies to a discrete plate body to form the weldment 100. Limiting distortion in the plate body 114 in turn may limit (or eliminate) optical effects of such distortion that could otherwise interfere with the ability of a non-contact temperature sensor optically coupled to the interior 104 (shown in FIG. 3) of the plate body 114 to acquire temperature of structures arranged within the interior 104 (shown in FIG. 3) of the weldment 100, limiting temperature variation (and associated cross-substrate thickness variation within material layers deposited onto substrates within weldment 100) by, for example within the material layer 4 (shown in FIG. 3) deposited onto the substrate 2 (shown in FIG. 3) supported within the weldment 100.

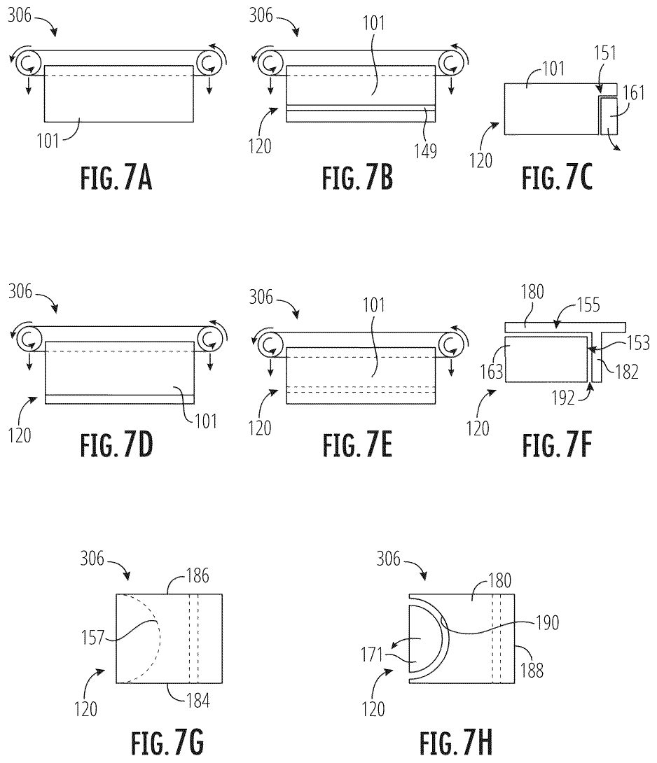

Referring once again to FIG. 4 and with continuing reference to FIG. 8 to FIG. 11, it is contemplated that the shelf body 120 be formed from a transparent material, for example the transparent material 102 (shown in FIG. 1), and have a shelf portion 180 and an end rib portion 182. The shelf portion 180 of the shelf body 120 is configured to convey fluid, for example the process fluid source 202 (shown in FIG. 1), through the interior 104 of the weldment 100 and toward the substrate 2 (shown in FIG. 1). In this respect it is contemplated that the shelf portion 180 be generally planar in shape, extend laterally between first lateral edge 184 (shown in FIG. 7G) and a second lateral edge 186 (shown in FIG. 7G). In further respect, it is also contemplated that the shelf portion 180 extend longitudinally between an injection flange-facing edge 188 (shown in FIG. 7H) and a divider-facing edge 190 (shown in FIG. 7H). It is contemplated that the end rib portion 182 of the shelf body 120 extend from the shelf portion 180, for example at a location longitudinally intermediate the injection flange-facing edge 188 (shown in FIG. 7H) and the divider-facing edge 190 (shown in FIG. 7H) of the shelf portion 180 of the shelf body 120, and that the end rib portion 182 laterally span the first lateral edge 184 (shown in FIG. 7G) and the second lateral edge 186 (shown in FIG. 7G) of the shelf portion 180 of the shelf body 120. In certain examples the shelf portion 180 of the shelf body 120 may be substantially orthogonal relative to the end rib portion 182 of the shelf body 120. In accordance with certain examples, the end rib portion 182 of the shelf body 120 may be sized and dimensioned to laterally span the first sidewall portion 126 and the second sidewall portion 128 of the channel body 112. The end rib portion 182 may further extends between the plate portion 124 of the channel body 112 and the plate body 114 of the weldment 100. It is also contemplated that the end rib portion 182 of the shelf body 120 may protrude laterally from the weldment 100, for example such that an end rib edge 192 is separated from the plate portion 124 of the channel body 112 by the plate body 114 included in the weldment 100.

It is contemplated that the shelf body 120 be coupled to both the channel body 112 and the plate body 114 by one or more welds. In this respect the shelf portion 180 of the shelf body 120 may be coupled to the first sidewall portion 126 of the channel body 112 by a first shelf body-to-first sidewall weld 194. The shelf portion 180 may further be coupled to the second sidewall portion 128 of the channel body 112 by a second shelf body-to-second sidewall weld 196. It is contemplated that the first shelf body-to-first sidewall weld 194 couple the first lateral edge 184 (shown in FIG. 7G) of the shelf portion 180 of the shelf body 120 to an interior surface of the first sidewall portion 126 of the channel body 112. It is also contemplated that the second shelf body-to-second sidewall weld 196 couple the second lateral edge 186 (shown in FIG. 7G) of the shelf portion 180 of the shelf body 120 to an interior surface of the second sidewall portion 128 of the channel body 112. In further respect, it is also contemplated that an end rib portion-to-plate body weld 198 may couple the end rib portion 182 of the shelf body 120 to the plate body 114 as well as the first sidewall portion 126 and the second sidewall portion 128 of the channel body 112, the end rib portion-to-plate body weld 198 laterally spanning the plate body 114, the end rib portion-to-plate body weld 198 longitudinally intermediate the injection flange-facing edge 188 (shown in FIG. 7H) and the divider-facing edge 190 (shown in FIG. 7H) of the shelf portion 180 of the shelf body 120.

With reference to FIG. 7A-H, It is contemplated that that the shelf body 120 have single, one-piece construction. In this respect it is contemplated that the shelf body be weldless, for example without any weld coupling the end rib portion 182 of the shelf body 120 to the shelf portion 180 of the shelf body 120. In this respect it is contemplated that the shelf portion 180 and the end rib portion 182 of the shelf body 120 be formed from a singular, one-piece shelf body workpiece 101 using a subtractive manufacturing technique. In certain examples the subtractive manufacturing technique may include a wire sawing technique, such as shown in FIGS. 7A-B and FIGS. D-E. In this respect it is contemplated that a first shelf body slab 161 may be separated from the shelf body workpiece 101 using the wire sawing technique, as shown in FIG. 7C, and that a second shelf body slab 163 may be separated using the wire sawing technique. In further examples a divider cutout plate 171 may be separated from the shelf portion 180 of the shelf body 120 using the wire sawing technique, as shown in FIG. 7H. In accordance with certain examples, the subtractive manufacturing technique may include a boring or drilling technique. In such examples the wire sawing operation and/or the boring or drilling operation may be followed by machining operation to define the final shape of the shelf portion 180 and the end rib portion 182 of the shelf body 120. As will be appreciated by those of skill in the art in view of the present disclosure, forming the shelf body 120 with a single, one-piece construction may limit (or eliminate) distortion otherwise imparted into the shelf portion 180 of the shelf body 120, promoting laminar flow of the process fluid 212 (shown in FIG. 1) within the weldment 100. As will also be appreciated by those of skill in the art in view of the present disclosure, forming the shelf portion 180 and/or the end rib portion 182 of the shelf body 120 using a wire sawing operation and/or a boring or drilling operation may also reduce the time otherwise required to fabricate the shelf body 120, limiting cost of the weldment 100.

Referring once again to FIG. 4 and FIG. 8 to FIG. 11, the injection flange body 116 is configured to provide communication between the interior 104 (shown in FIG. 3) of the weldment and the external environment 216 (shown in FIG. 1) outside of the weldment 100 and in this respect be formed from a transparent material, for example the transparent material 102 (shown in FIG. 3). In further respect, it is contemplated that the injection flange body 116 define therethrough an injection end slot 103 sized and dimensioned such that the substrate 2 may be loaded therethrough. It is contemplated that the injection flange body 116 be coupled to the weldment 100 by an injection end weld 165, the injection end weld 165 extending about the injection end slot 103, the injection end weld 165 further coupling the injection flange body 116 to both the channel body 112 and the plate body 114 included in the weldment 100.

In certain examples the injection end weld 165 may directly couple the injection flange body 116 to the channel body 112. In accordance with certain examples, the injection end weld 165 may indirectly couple the injection flange body 116 to the plate body 114 indirectly, through the shelf body 120, the single, one-piece construction of the shelf body 120 preventing heating of the shelf body 120 collateral to forming of the injection end weld 165 from distorting the planar contour of the shelf portion 180 of the shelf body 120. It is contemplated that the injection flange body 116 may be formed using a subtractive manufacturing technique. Examples of suitable subtractive manufacturing techniques include machining operations like milling and boring as well as cutting operations, such as wire sawing operations. As will be appreciated by those of skill in the art in view of the present disclosure, preventing distortion of the planar contour of the shelf portion 180 of the shelf body 120 due to collateral heating may limit cross-substrate variation of the material layer 4 (shown in FIG. 1) deposited onto the substrate 2 (shown in FIG. 1), for example by ensuring that the contour of the shelf portion 180 promotes laminar flow of the process fluid 212 (shown in FIG. 1) conveyed across the shelf body 120 prior to arrival of the substrate 2 via the divider 266 (shown in FIG. 3).

The exhaust flange body 118 may be similar to the injection flange body 116 and additionally be separated from injection flange body 116 by both the channel body 112 and the plate body 114 included in the weldment 100. It is contemplated that the exhaust flange body 118 define therethrough an exhaust end slot 107, which may be configured to provide communication between the interior 104 (shown in FIG. 3) of the weldment 100 and the exhaust source 206 (shown in FIG. 1), and which may be sized and configured to promote laminar flow within the interior 104 and the weldment 100 and the exhaust manifold 254 (shown in FIG. 3). It further contemplated that the exhaust flange body 118 may be coupled to the weldment 100 by an exhaust end weld 109, which may extend about the exhaust end slot 107, and which may couple the exhaust flange body 118 to both the channel body 112 and the plate body 114 included in the weldment 100. In certain examples the exhaust end slot 107 may have a wider width than the divider 266 (shown in FIG. 3), enabling installation of the process kit 264 (shown in FIG. 3) within the weldment 100 from a service end of the chamber arrangement 204 (shown in FIG. 3), such as when employed in a cluster-type platform architecture.

As above, it is contemplated that the single, one piece construction of the channel body 112 resist deformation collateral to heating of the channel body 112 during forming of the exhaust end weld 109, promoting laminar flow of the process fluid 212 (shown in FIG. 1) within the upper chamber 274 (shown in FIG. 3) of the weldment 100. Notably, as the above-described wire sawing operation enables the plurality of first sidewall rib portions 144 and the plurality of second sidewall rib portions 148 to extend from the first sidewall portion 126 and the second sidewall portion 128 of the channel body 112, respectively, and without a gap therebetween, longitudinal strength of the otherwise plate-like first sidewall portion 126 and second sidewall portion 128 is sufficient to resist deformation due to collateral heating during the forming the exhaust end weld 109. As above, this also promotes laminar flow within the upper chamber 274 of the weldment 100, further limiting cross-substrate material layer variation otherwise associated with non-laminar flow of the process fluid 212.

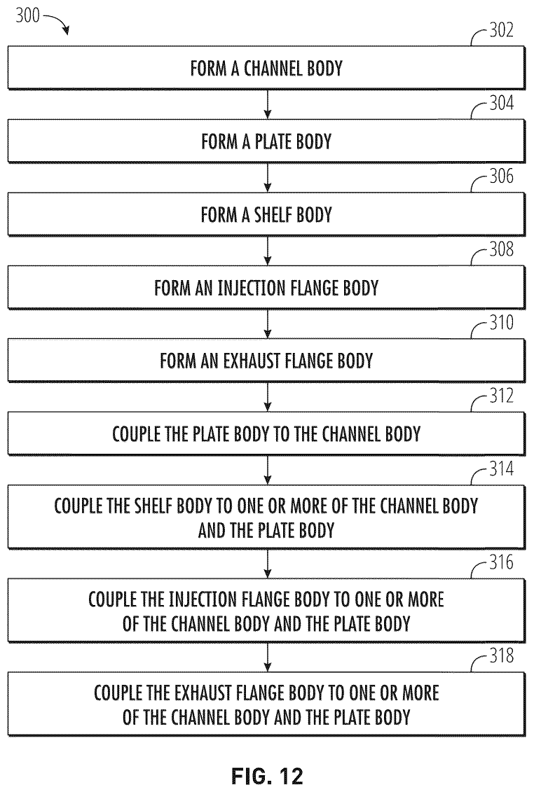

With reference to FIG. 12 to FIG. 16, a method 300 of making a weldment, e.g., the weldment 100 (shown in FIG. 1), is shown. Referring to FIG. 12, the method 300 generally includes forming channel body and a plate body using a subtractive manufacturing technique, e.g., the channel body 112 (shown in FIG. 4) and the plate body 114 (shown in FIG. 4), as shown with box 302 and box 304. In the illustrated example the method 300 also includes forming a shelf body and an injection flange body using a subtractive manufacturing technique, e.g., the shelf body 120 (shown in FIG. 4) and the injection flange body 116 (shown in FIG. 4), as shown with box 306 and box 308. As shown with box 310, the method 300 may further includes forming an exhaust flange body using a subtractive manufacturing technique, e.g., the exhaust flange body 118 (shown in FIG. 4). It is contemplated that the plate body be coupled to the channel body by forming a weld between the plate body and the channel body, e.g., the first sidewall weld 158 (shown in FIG. 8) and the second sidewall weld 160 (shown in FIG. 8), as shown with box 312. It is also contemplated that the shelf body be coupled to one or more of the channel body and the plate by forming a weld between the shelf body and the one or more of the channel body and the plate body, e.g., one or more of the first lateral weld (shown in FIG. 8) and the second lateral weld (shown in FIG. 8), as shown with box 314. It is further contemplated that the injection flange body be coupled to the channel body and the plate body by an injection end weld, e.g., the injection end weld 165 (shown in FIG. 8), and that the exhaust flange body may be coupled to the channel body and the plate body by an exhaust end weld, e.g., the exhaust end weld 109 (shown in FIG. 8), as a shown with box 316 and box 318.

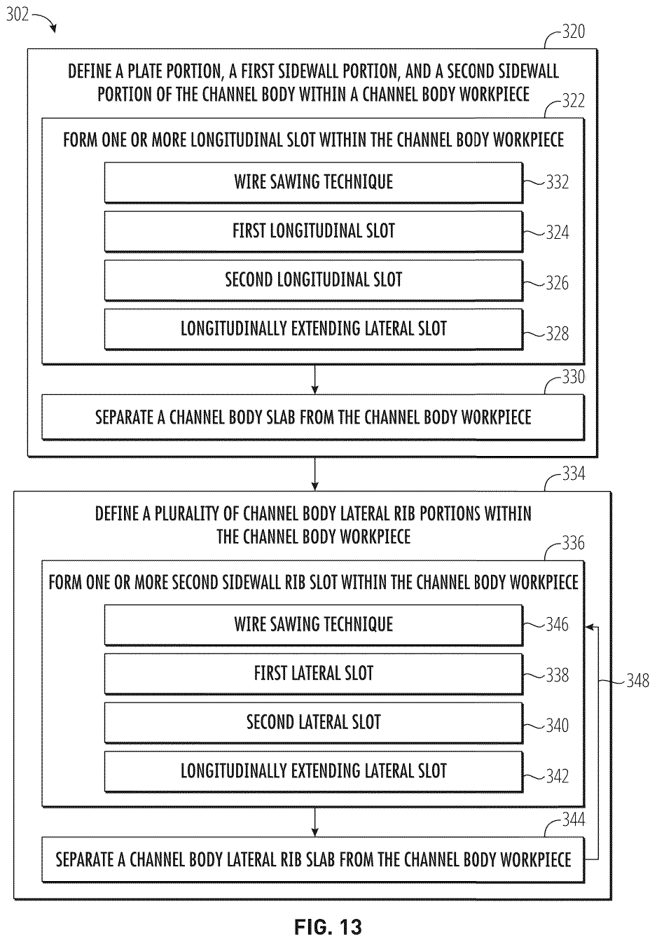

Referring to FIG. 13 and with further reference to FIGS. 5A-5H, forming 302 the channel body may include defining a plate portion, a first sidewall portion, and a second sidewall portion within a channel body workpiece, e.g., the plate portion 124 (shown in FIG. 4), the first sidewall portion 126 (shown in FIG. 4), and the second sidewall portion 128 (shown in FIG. 4) within the one-piece channel body workpiece 136 (shown in FIGS. 5A-5C), as shown with box 320. It is contemplated that one or more longitudinal slot may be formed within the channel body workpiece, as shown with box 322. In certain examples forming the one or more longitudinal slot may include forming a plurality of longitudinal slots within the channel body workpiece, as also shown with box 322. In this respect it is contemplated that a first longitudinal slot and a second longitudinal slot may be formed within the channel body workpiece, e.g., a first longitudinal slot 111 (shown in FIG. 5B) and a second longitudinal slot 113 (shown in FIG. 5B), as shown with box 324 and box 326. The first longitudinal slot and the second longitudinal slot may define the first sidewall portion and the second sidewall portion of the channel body in near-net form, respectively, and a longitudinally extending lateral slot may be formed within the channel body workpiece coupling the first longitudinal slot to the second longitudinal slot to define the plate portion of the channel body in near-net form, e.g., the longitudinally extending lateral slot 115 (shown in FIG. 5B), as shown with box 328. It is contemplated that a channel body slab be separated from the channel body workpiece using the one or more longitudinal slot defined within the channel body workpiece, e.g., the channel body slab 138 (shown in FIG. 5B), as shown with box 330. In certain examples the one or more longitudinal slot and/or the longitudinally extending lateral slot may be formed using a wire sawing technique, as shown with box 332. It is also contemplated that channel body slab may be separated from the channel body workpiece using fewer slots defined using the wire sawing technique, for example by forming a singular longitudinal slot within the channel body workpiece and remain within the scope of the disclosure, as also shown with box 322.

In certain examples forming 302 the channel body may include defining a plurality of channel body lateral rib portions within the plate portion of the channel body, e.g., the plurality of channel body rib portions 140 (shown in FIG. 8), as shown with box 334. Defining 334 the plurality of channel body lateral rib portions may in turn include forming one or more lateral slot within the channel body workpiece, as shown with box 336. In certain examples forming 336 the one or more lateral slot may include forming a first lateral slot and a second lateral slot within the channel body workpiece, e.g., the first lateral slot 115 (shown in FIG. 5B) and the second lateral slot 117 (shown in FIG. 5D), as shown with box 338 and box 340. In such examples forming the one or more lateral slot may include forming a longitudinally extending lateral slot within the channel body workpiece, e.g., the longitudinally extending lateral slot 121 (shown in FIG. 5D), as shown with box 342. In certain examples a plate portion rib slab from the channel body workpiece may be separated from the channel body workpiece using the one or more lateral slot formed within the channel body workpiece, e.g., the channel body lateral rib slab 142 (shown in FIG. 5D), as shown with box 344.

It is contemplated that the one or more lateral slot may be formed using a wire sawing technique, as shown with box 346. It is also contemplated and that the aforementioned subtractive manufacturing operations may be repeated at a plurality of longitudinally offset locations along the channel body workpiece, for example to define twelve (12) chamber body lateral rib portions, and remain within the scope of the present disclosure, as shown with arrow 348, and that the defining the plurality of channel body lateral rib portions may alternatively (or additionally) include drilling or boring the channel body workpiece, as also shown with box 346.

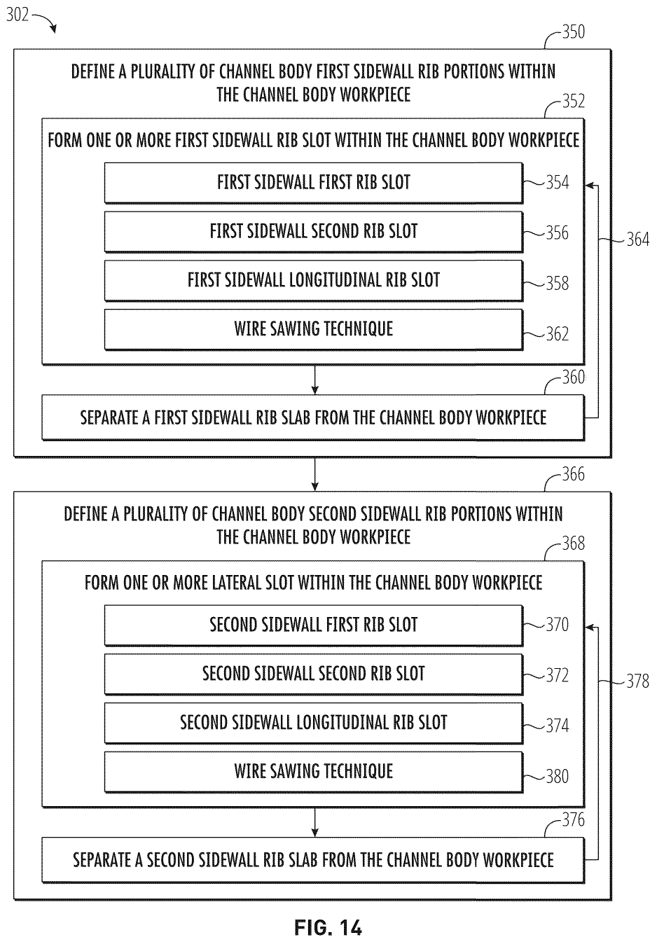

Referring to FIG. 14 and with continuing reference to FIGS. 5A-5H, forming 302 the channel body may include defining a plurality of first sidewall rib portions within an exterior surface of the channel body workpiece, e.g., the plurality of first sidewall rib portions 144 (shown in FIG. 8), as shown with box 350. Defining 350 the plurality of channel body first rib portions may include forming one or more first sidewall rib slot within the exterior surface of the channel body workpiece using a subtractive manufacturing technique, as shown with box 352. In certain examples forming 352 the one or more first sidewall slot may include forming a first sidewall first rib slot and a first sidewall second rib slot within the exterior surface of the channel body workpiece, e.g., the first sidewall first rib slot 125 (shown in FIG. 5F) and the first sidewall second rib slot 127 (shown in FIG. 5F), as shown with box 354 and box 356. In such examples a first sidewall longitudinal rib slot may further be defined within the channel body workpiece, e.g., the first sidewall longitudinal rib slot lateral slot 129 (shown in FIG. 5F), as shown with box 358. The first sidewall longitudinal rib slot may couple the first sidewall second rib slot to the first sidewall first rib slot, as also shown with box 358. Forming 352 the one or more first sidewall rib slot within the channel body workpiece may further include separating a first sidewall rib slab from the channel body workpiece, e.g., the first sidewall rib slab 146 (shown in FIG. 5F), as shown with box 360. The one or more first sidewall rib slots may be formed using a wire sawing technique, for example to define near net shape of opposing faces of longitudinally adjacent ones of the plurality of first sidewall rib portions, as shown with box 362.

In certain examples Defining 350 the plurality of first sidewall rib portions may include defining the plurality of first sidewall rib portions at locations longitudinally offset from one another along the first sidewall portion of the channel body, for example at longitudinal locations wherein each of the plurality of first sidewall rib portions extend continuously from a respective one of the plurality of channel body lateral rib portions. In this respect it is contemplated that forming 352 the first sidewall rib slot may be repeated at locations longitudinally spaced apart between an injection end and an exhaust end of the channel body to define the plurality of first sidewall rib portions within the channel body workpiece, for example to define twelve (12) first sidewall rib portions along a longitudinal length of the channel body workpiece, as shown with arrow 364. It is also contemplated that other types of subtractive manufacturing processes may be employed to define near net shape of opposing faces of longitudinally adjacent ones of the plurality of first sidewall rib portions, such as boring and/or drilling as well as machining, and remain within the scope of the present disclosure.

It is contemplated that forming 302 the channel body may further include defining a plurality of second sidewall rib portions within an exterior surface of the channel body workpiece, e.g., the plurality of second sidewall rib portions 148 (shown in FIG. 5H), as shown with box 366. Defining 366 the plurality of channel body first rib portions may include forming one or more second sidewall rib slot within the exterior surface of the channel body workpiece using a subtractive manufacturing technique, as shown with box 368. In certain examples forming 368 the one or more second sidewall rib slot may include forming a second sidewall first rib slot and a second sidewall second rib slot within the exterior surface of the channel body workpiece, e.g., the second sidewall first rib slot 131 (shown in FIG. 5H) and the second sidewall second rib slot 133 (shown in FIG. 5H), as shown with box 370 and box 372. In such examples a second sidewall longitudinal rib slot may further be defined within the channel body workpiece, e.g., the second sidewall longitudinal rib slot 169 (shown in FIG. 5H), as shown with box 374. It is contemplated that second sidewall longitudinal rib slot may couple the second sidewall second rib slot to the second sidewall first rib slot, as also shown with box 374. It is also contemplated that forming 368 the one or more second sidewall rib slot within the channel body workpiece may thereby include separating a second sidewall rib slab from the channel body workpiece, e.g., the second sidewall rib slab 150 (shown in FIG. 5H), as shown with box 376.

In certain examples Defining 366 the plurality of second sidewall rib portions may include defining the plurality of second sidewall rib portions at locations longitudinally offset from one another along the second sidewall portion of the channel body. In this respect it is contemplated that the plurality of second sidewall rib portions may be defined at longitudinal locations wherein each of the plurality of second sidewall rib portions extend continuously from a respective one of the plurality of channel body lateral rib portions and laterally overlap respective ones of the plurality of first sidewall rib portions. In accordance with certain examples, the above-described operation for forming 368 the second sidewall rib slot may be repeated at locations longitudinally spaced apart between the injection end and the exhaust end of the channel body to define the plurality of second sidewall rib portions within the channel body workpiece, for example to define twelve (12) second sidewall rib portions along the longitudinal length of the channel body workpiece, as shown with arrow 378. As above, it is also contemplated that the one or more second sidewall rib slot may be formed using a wire sawing technique, for example to define near net shape of opposing faces of longitudinally adjacent ones of the plurality of second sidewall rib portions, as shown with box 380, and that other types of subtractive manufacturing processes may be employed to define near net shape of opposing faces of longitudinally adjacent ones of the plurality of first sidewall rib portions, such as boring and/or drilling as well as machining, and remain within the scope of the present disclosure.

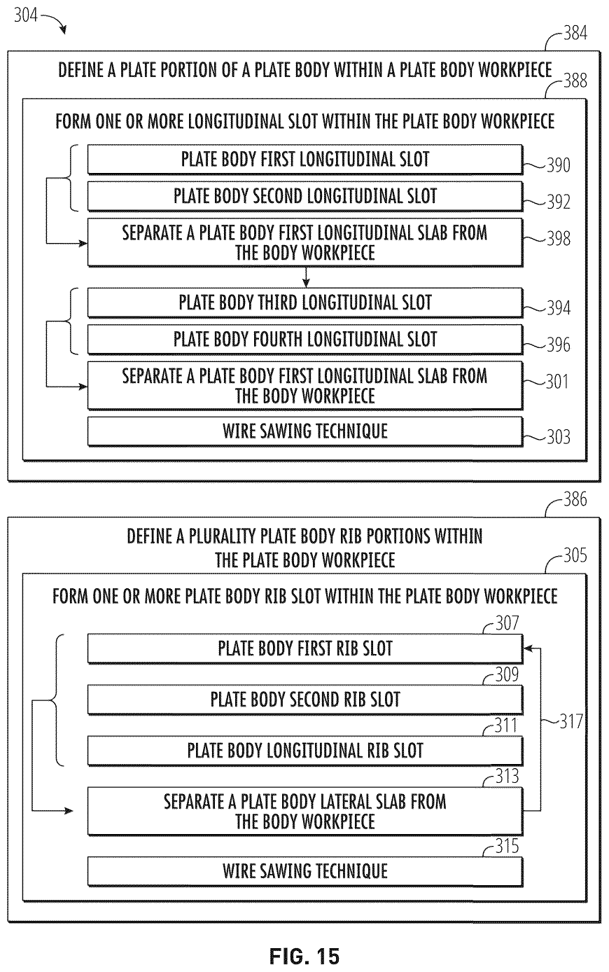

Referring to FIG. 15 and with continuing reference to FIG. 6A-J, forming 304 the plate body 114 may include defining a plate portion and a plurality of plate body rib portions in a plate body workpiece, e.g., the plate portion 170 (shown in FIG. 4) and the plurality of plate body rib portions 166 (shown in FIG. 4) in the plate body workpiece 172 (shown in FIG. 6A), as shown with box 384 and box 386. Defining 384 the plate portion of the plate body may include defining one or more longitudinal plate body slot within the plate body workpiece, as shown with box 388. In this respect it is contemplated that a plate body first longitudinal slot and a plate body second longitudinal slot may be formed within surfaces of a common lateral side of the plate body workpiece, e.g., the plate body first longitudinal slot 135 (shown in FIG. 6B) and the plate body second longitudinal slot 137 (shown in FIG. 6C), as shown with box 390 and box 392. In further respect, it is also contemplated that a plate body third longitudinal slot and a plate body fourth longitudinal slot may be formed within surfaces of common lateral side of the plate body workpiece, e.g., the plate body third longitudinal slot 139 (shown in FIG. 6E) and the plate body fourth longitudinal slot 141 (shown in FIG. 6F), for example on a side of the plate body workpiece laterally opposite the plate body first longitudinal slot and the plate body second longitudinal slot, as shown with box 394 and box 396.

In certain examples the plate body second longitudinal slot may intersect the plate body first longitudinal slot to separate a first plate body longitudinal slab from the plate body workpiece, e.g., the first plate body longitudinal slab 174 (shown in FIG. 6C), as shown with box 398. In accordance with certain examples, the plate body fourth longitudinal slot intersect the plate body third longitudinal slot to separate a plate body second longitudinal slab from the plate body workpiece, e.g., the second plate body longitudinal slab 176 (shown in FIG. 6F), as shown with box 301. It is contemplated that the plate body second longitudinal slot may be substantially orthogonal relative to the plate body first longitudinal slot, and the plate body fourth longitudinal slot may be substantially orthogonal relative to the plate body third longitudinal slot, as also shown with box 301. It is also contemplated that one or more of the aforementioned longitudinal slots may be formed using a wire sawing technique, as shown with box 303.

Defining 386 the plurality of plate body rib portions may include forming one more or more plate body rib slot within a surface of the plate body workpiece, as shown with box 305. In this respect it is contemplated that a plate body first rib slot and a plate body second rib slot may be formed within the surface of the plate body workpiece, e.g., the plate body first rib slot 143 (shown in FIG. 6I) and the plate body second rib slot 145 (shown in FIG. 6I), as shown with box 307 and with box 309. The plate body first rib slot may extend only partially through a thickness of the plate body workpiece, as shown with box 307. The plate body second rib slot may also extend only partially through the thickness of the plate body workpiece, be longitudinally offset from the plate body first rib slot, and be substantially parallel to the plate body first rib slot, as also shown with box 309. It is contemplated that a plate body longitudinal rib slot be formed within the plate body workpiece, e.g., the plate body longitudinal rib slot 147 (shown in FIG. 6J), as shown with box 311. The plate body longitudinal rib slot may couple the plate body second rib slot to the plate body first rib slot, the one or more rib slot formed within the plate body workpiece thereby separating a plate body lateral slab from the plate body workpiece, e.g., the plate portion rib slab 178 (shown in FIG. 6J), as shown with box 313. In certain examples forming the one or more rib slot may be accomplished using a wire sawing technique, for example to define near-net shapes of opposing faces of longitudinally adjacent plate body lateral ribs, as shown with box 315. It is also contemplated that other subtractive manufacturing techniques may be employed to define the near-net shapes of the opposing faces of the longitudinally adjacent plate body lateral ribs, such as boring and/or drilling as well as certain machining techniques, and remain within the scope of the present disclosure.

In certain examples Defining 384 the plurality of plate body rib portions may include defining the plurality of plate body rib portions at locations longitudinally offset from one another along the plate portion of the plate body, for example at a spacing substantially equivalent to spacing of the channel body rib portions. In this respect it is contemplated that the plurality of plate body rib portions may protrude laterally from the plate portion of the plate body. In further respect, the plurality of plate body rib portions may substantially conform in length to lateral extremes of the plurality first sidewall ribs and the plurality of second sidewall ribs. In accordance with certain examples, forming 301 the one or more plate body rib slot may be repeated at locations longitudinally spaced apart between the injection end and the exhaust end of the plate, for example to define eleven (11) plate body rib portions along the longitudinal length of the plate body workpiece, as shown with arrow 317. It is contemplated that the plurality of plate body rib portions be equivalent to the plurality of channel body rib portions, first sidewall rib portions, and second sidewall rib portions.

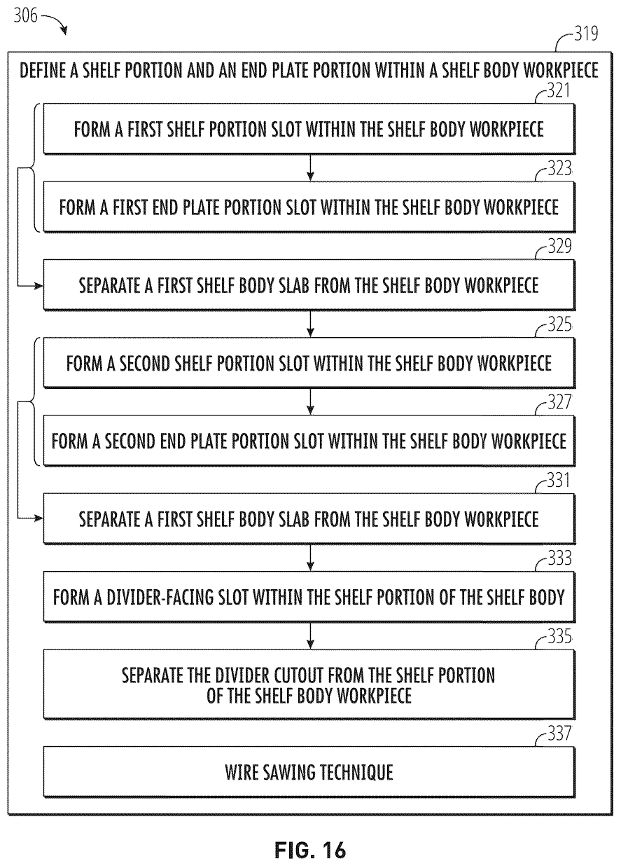

Referring to FIG. 16 and with continuing reference to FIG. 7A-H, forming 306 may include defining the shelf portion and an end rib portion in a shelf body workpiece, e.g., the shelf portion 180 (shown in FIG. 4) and the end rib portion 182 (shown in FIG. 4) within the shelf body workpiece 101 (shown in FIG. 7A), as shown with box 319. Defining the shelf portion of the shelf body may include forming a first shelf portion slot and a second shelf portion slot within the shelf body workpiece, e.g., the first shelf portion slot 149 (shown in FIG. 7B) and the second shelf portion slot 151 (shown in FIG. 7C), as shown with box 321 and box 323. Defining the end rib portion of the shelf body may include forming a first end plate slot and a second end plate slot within the shelf body workpiece, e.g., the first end plate slot 153 (shown in FIG. 7F) and the second end plate slot 155 (shown in FIG. 7F), as shown with box 325 and box 327. It is contemplated that the first end plate slot intersect the first shelf portion slot such that a first shelf portion slab is separated from the shelf body workpiece, e.g., the first shelf body slab 161 (shown in FIG. 7C), as shown with box 329. It is also contemplated that the second end plate slot intersect the second shelf portion slot such that a second shelf portion slab is separated from the shelf body workpiece, e.g., the second shelf body slab 163 (shown in FIG. 7F), as shown with box 331.

In certain examples defining 319 the shelf body may further include forming a divider-facing slot formed within the shelf portion of the shelf body workpiece, e.g., the divider-facing slot 157 (shown in FIG. 7G), and a divider cutout removed from the shelf portion the shelf body workpiece, e.g., the divider cutout plate 171 (shown in FIG. 7H), as shown with box 333 and box 335. In certain examples one or more of the aforementioned shelf body workpiece slots may be formed using a wire sawing technique, as shown with box 337. It also contemplated that another subtractive manufacturing technique may be employed, for example milling or grinding, and remain within the scope of the present disclosure.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

1. A weldment, comprising:
a channel body formed from a ceramic material having:
a plate portion having a first surface and a second surface;
a first sidewall portion extending from the plate portion, the first sidewall portion substantially orthogonal relative to the first surface of the plate portion; and
a second sidewall portion spaced apart from the first sidewall portion and substantially parallel to the first sidewall portion of the channel body,
wherein the channel body has single, one-piece construction with no welds formed using a subtractive manufacturing technique to limit optical effects associated with dimensional variation otherwise introduced into the channel body by welding.

2. The weldment of claim 1, wherein the channel body has a plurality of channel body rib portions extending from the second surface of the plate portion, wherein the plurality of channel body rib portions are formed using the subtractive manufacturing technique.

3. The weldment of claim 2, wherein the plurality of channel body rib portions are substantially orthogonal relative to the first sidewall portion of the channel body.

4. The weldment of claim 2, wherein one or more of the plurality of channel body rib portions span the plate portion of the channel body, wherein the first sidewall portion has a plurality of first sidewall rib portions each extending from respective ones of the plurality of channel body rib portions defined using a wire sawing technique, and wherein the second sidewall portion has a plurality of second sidewall rib portions each extending from the respective ones of the plurality of channel body rib portions defined using a the wire sawing technique.

5. The weldment of claim 1, further comprising:
a plate body formed from the ceramic material and separated from the plate portion of the channel body by the first sidewall portion and the second sidewall portion of the channel body;
a first sidewall weld coupling the plate body to the first sidewall portion; and
a second sidewall weld coupling the plate body to the second sidewall portion of the channel body, the second sidewall weld being substantially parallel to the first sidewall weld.

6. The weldment of claim 5, wherein the plate body defines a passthrough, the weldment further comprising:
a tubulation body separated from the channel body by the plate body; and
a tubulation body weld coupling the tubulation body to the plate body.

7. The weldment of claim 5, wherein the plate body has an interior surface and a ribbed surface with a plurality of rib portions extending therefrom, the interior surface facing the channel body, wherein the plate body has a singular, one-piece construction with no welds formed using a subtractive manufacturing technique to limit optical effects associated with dimensional variation otherwise introduce into the channel body by welding.

8. The weldment of claim 7, wherein the channel body has a plurality a rib portions extending from the first sidewall portion of the channel body, and wherein the plurality of rib portions extending from the plate body are joined to the plurality of rib portions extending from the first sidewall portion by intervening welds.

9. The weldment of claim 1, further comprising:
an injection flange body abutting the channel body; and
an injection end weld coupling the injection flange body to the plate portion of the channel body, the first sidewall portion of the channel body, and the second sidewall portion of the channel body.

10. The weldment of claim 1, further comprising:
a shelf body formed from the ceramic material having:
a shelf portion separating the first sidewall portion of the channel body from the second sidewall portion of the channel body;
an end rib portion extending from the shelf portion and substantially orthogonal to the shelf portion of the shelf body;
a first shelf body-to-first sidewall weld coupling the shelf body to the first sidewall portion of the channel body; and
a second shelf body-to-second sidewall weld coupling the shelf body to the second sidewall portion of the channel body,
wherein the shelf body has single, one-piece construction with no welds formed using a subtractive manufacturing technique to limit fluid flow effects associated with dimensional variation otherwise introduced into the shelf portion of the shelf body by welding the shelf portion of the shelf body to the end rib portion of the shelf body.

11. The weldment of claim 10, further comprising:
an exhaust flange body abutting the channel body; and
an exhaust end weld coupling the exhaust flange body to the shelf portion of the shelf body, the first sidewall portion of the channel body, and the second sidewall portion of the channel body.

12. The weldment of claim of claim 1, wherein the subtractive manufacturing technique includes at least a wire sawing operation.

13. The weldment of claim 1, further comprising a slab removed from a singular one-piece workpiece during forming of the channel body using the subtractive manufacturing technique.

14. A semiconductor processing system, comprising:
a process fluid source including a silicon-containing material layer precursor;
a chamber arrangement coupled to the process fluid source including:
a weldment as recited in claim 1; and
a substrate support arranged within the weldment and supported therein for rotation about a rotation axis, the substrate support configured to seat thereon a substrate during at least one of deposition of a material layer onto the substrate and removal of material from the substrate; and
an exhaust source coupled to process fluid source by the weldment.

15. A method of making a weldment, comprising:
forming a channel body from a single, one-piece channel body workpiece formed from a ceramic material, the channel body having a plate portion with a first surface and a second surface, a first sidewall portion extending from the plate portion and substantially orthogonal relative to the first surface of the plate portion, and a second sidewall portion spaced apart from the first sidewall portion and substantially parallel to the first sidewall portion,
forming a plate body;
coupling the plate body to the channel body; and
wherein the channel body has a single, one-piece construction with no welds formed using a subtractive manufacturing technique to limit optical effects associated with dimensional variation otherwise introduced into the channel body by welding.

16. The method of claim 15, wherein one or more of the channel body and the plate body is formed using a wire sawing technique.

17. The method of claim 15, further comprising:
forming one or more lateral slot within the channel body workpiece using a wire sawing technique;
forming one or more first sidewall rib slot within the channel body workpiece using the wire sawing technique; and
forming one or more second sidewall rib slot within the channel body workpiece using the wire sawing technique.

18. The method of claim 15, wherein coupling the plate body to the channel body comprises:
forming a first sidewall weld between the plate body and the first sidewall portion of the channel body; and
forming a second sidewall weld between the plate body the second sidewall portion of the channel body.

19. The method of claim 15, further comprising:
forming a shelf body using a wire sawing technique; and
coupling the shelf body to one or more of the channel body and the plate body.

20. The method of claim 15, further comprising:
coupling an injection flange body to the channel body using an injection end weld; and
coupling an exhaust flange body to the channel body using an exhaust end weld.
